(19) United States
(12) Patent Application Publication
(10) Pub. No.: US 2007/0263713 A1
(43) Pub. Date: Nov. 15, 2007

(54) Digital video interface

(76) Inventor: Lewis B. Aronson, Los Altos, CA (US)

Correspondence Address: MORGAN, LEWIS & BOCKIUS, LLP., 2 PALO ALTO SQUARE, 3000 EL CAMINO REAL, PALO ALTO, CA, 94306, US

(21) Appl. No.: 11/431,339

(22) Filed: May 9, 2006

(51) Int. Cl. H03H 7/30

(52) U.S. Cl. 375/229

(57) ABSTRACT

A circuit includes a first interface to receive a plurality of data streams from a plurality of signal inputs, a multiplexer to interleave the plurality of data streams into a serial data stream, and an output driver, including pre-emphasis circuitry, to transmit the serial data stream on a first output. The plurality of data streams may correspond to digital video. The plurality of data streams may be encoded using transition-minimized differential signaling. The first output may be configured to couple to a cable to convey electrical signals.

### FIELD

The subject matter disclosed herein relates generally to electrical interfaces, and in particular to interfaces between digital video signals and cables to convey electrical signals.

### BACKGROUND

Digital audio and video formats, including high definition television, are increasingly popular. Transferring data corresponding to such formats, however, may utilize a high bandwidth. As a consequence, digital interfaces, such as the digital video interface and the high-definition multimedia interface (HDMI), are also increasingly popular. For example, HDMI includes three links (for red, green and blue information) as well as a clock link. Each HDMI link may be able to transfer up to 24 bits of data per pixel at about 165 Mpixels per second, which corresponds to a bandwidth of about 4 Gb/s (four gigabits per second) for each link. These four links are typically transmitted on a set of four twisted pairs combined with lines for a few other low frequency control signals.

While popular, digital interfaces such as HDMI often entail additional limitations. In addition, these digital interfaces may have reduced performance when utilized with low-cost electrical cables, such as the parallel set of twisted pairs mentioned above, that are often found in consumer applications. The reduced performance of the digital interfaces may reduce an effective communication distance to some 5-10 m. The existing cables are also limited in that they may not allow field termination, which may limit the ability to run lines through walls and crawlspaces. There is a need, therefore, for an improved electrical interface between low-cost electrical cables and high bandwidth digital interfaces.

### SUMMARY

A circuit is described. The circuit includes a first interface configured to receive a plurality of data streams from a plurality of signal inputs, a multiplexer configured to interleave the plurality of data streams into a serial data stream, and an output driver, including pre-emphasis circuitry, configured to transmit the serial data stream on a first output. The plurality of data streams may correspond to digital video (e.g., a digital video data stream). The plurality of data streams may be encoded using transition-minimized differential signaling. The first output may be configured to couple to a cable to convey electrical signals.

In some embodiments, the plurality of data streams may correspond to a digital video interface format. In some embodiments, the plurality of data streams may correspond to a high definition multimedia interface format.

The cable may include a cable television cable, a twisted pair, a twin coax cable, a cable having a characteristic impedance of substantially 50 Ω, or a cable having a characteristic impedance of substantially 75 Ω. The cable may have a length greater than a pre-determined value. The pre-determined value may be 5 m.

The output driver transmitting the serial data stream may include circuitry for performing a signal transformation corresponding to the first characteristic impedance. The serial data stream may have a data rate greater than 3 Gb/s. The serial data stream may have a data rate less than 5 Gb/s.

In some embodiments, the cable may have a characteristic impedance and a communication bandwidth characterized by a first frequency threshold and a second frequency threshold. The first frequency threshold may be less than the second frequency threshold. The cable may have a frequency response band between the first frequency threshold and the second frequency threshold. The circuit may perform channel coding on the serial data stream such that a minimum frequency of content in the serial data stream exceeds the first frequency threshold.

In some embodiments, the circuit may further include a second interface configured to receive a return signal from a cable input. The cable input may be configured to couple to the cable. The return signal may have a maximum frequency that is less than the first frequency threshold. In some embodiments, the serial data stream and the return signal are communicated using a common cable, albeit in opposite directions.

In an alternate embodiment, the output driver is configured to receive the serial data stream including the plurality of data streams, to perform pre-emphasis and to transmit the serial data stream on the first output. The plurality of data streams may correspond to digital video. The plurality of data streams may be encoded using transition-minimized differential signaling. The first output may be configured to couple to the cable to convey electrical signals.

In an alternate embodiment, a circuit includes a third interface configured to receive the serial data stream, which is generated from a plurality of data streams from a signal input. The circuit also includes an adaptive equalizer, and a de-multiplexer configured to separate the plurality of data streams in the serial data stream into a plurality of signal outputs. The plurality of data streams may correspond to digital video. The plurality of data streams may be encoded using transition-minimized differential signaling. The signal input may be configured to couple to the cable to convey electrical signals. The adaptive equalizer may correct for a communications characteristic of the cable, such as limited bandwidth. For example, the adaptive equalizer may apply pre-emphasis to the plurality of data streams.

In an alternate embodiment, an input circuit includes the third interface configured to receive the serial data stream including the plurality of data streams, to perform adaptive equalization and to transmit the serial data stream on a second output. The plurality of data streams may correspond to digital video. The plurality of data streams may be encoded using transition-minimized differential signaling. The input may be configured to couple to the cable to convey electrical signals.

In an alternate embodiment, a circuit may include the first interface, which may be configured to receive the plurality of data streams from the plurality of signal inputs. The plurality of data streams may correspond to digital video having 768 or more vertical lines and an aspect ratio of 16:9. The data streams may be compatible with the digital video interface format. The multiplexer may be configured to interleave the plurality of data streams into the serial data stream. The serial data stream may have a data rate greater than a pre-determined threshold. The output driver, including pre-emphasis circuitry, may be configured to transmit the serial data stream on the first output. The first output may be configured to couple to the cable to convey electrical signals.

### BRIEF DESCRIPTION OF THE DRAWINGS

For a better understanding, reference should be made to the following detailed description taken in conjunction with the accompanying drawings, in which:

FIG. 1A is a block diagram illustrating an existing digital video interface system.

FIG. 1B is a block diagram illustrating an existing digital video interface system.

FIG. 2A is a block diagram illustrating an embodiment of a digital video interface system.

FIG. 2B is a block diagram illustrating an embodiment of a digital video interface system.

FIG. 3A is a block diagram illustrating an embodiment of a digital video interface system.

FIG. 3B is a block diagram illustrating an embodiment of a digital video interface system.

FIG. 4A is a block diagram illustrating an embodiment of a serializer circuit.

FIG. 4B is a block diagram illustrating an embodiment of a de-serializer circuit.

FIG. 5 is a diagram illustrating the communications bandwidth of a cable or other communications channel.

FIG. 6 is a flow diagram illustrating a method of operation of an embodiment of a digital video interface driver.

FIG. 7 is a flow diagram illustrating a method of operation of an embodiment of a digital video interface circuit.

FIG. 8 is a flow diagram illustrating a method of operation of an embodiment of a digital video interface input circuit.

FIG. 9 is a flow diagram illustrating a method of operation of an embodiment of a digital video interface circuit.

FIG. 10 is a block diagram illustrating an embodiment of a system.

Like reference numerals refer to corresponding parts throughout the drawings.

### DETAILED DESCRIPTION OF EMBODIMENTS

Reference will now be made in detail to embodiments, examples of which are illustrated in the accompanying drawings. In the following detailed description, numerous specific details are set forth in order to provide a thorough understanding of the present invention. However, it will be apparent to one of ordinary skill in the art that the present invention may be practiced without these specific details. In other instances, well-known methods, procedures, components, and circuits have not been described in detail so as not to unnecessarily obscure aspects of the embodiments.

Embodiments of interfaces for digital video, including digital video corresponding to high definition television, such as those having 768 or more vertical lines and an aspect ratio of 16:9, are described. In some embodiments, an external driver is coupled to a serializer circuit and an external receiver is coupled to a de-serializer circuit. The serializer circuit converts a plurality of data streams into a serial data stream and the de-serializer circuit converts the serial data stream into the plurality of data streams. The driver and receiver allow the serial data stream, including signals corresponding to an interface standard such as the digital video interface and/or the high-definition multimedia interface (HDMI), to be communicated (i.e., transmitted and received) on a cable that conveys electrical signals. The plurality of data streams may, therefore, each correspond to data streams that are encoded using transition-minimized differential signaling. In some embodiments, however, the plurality of data streams may be encoded using another DC balanced code. In some embodiments, the plurality of data streams may each have a data rate of about 1.65 Gb/s. In some embodiments, the plurality of data streams include packetized data.

The driver may include pre-emphasis and/or may perform a signal transformation corresponding to an impedance of the cable (e.g., impedance matching). Pre-emphasis includes boosting of certain frequency content in signals (typically the higher frequency content) to compensate for a frequency response of a channel, such as roll off at high frequencies. The receiver may include equalization and/or adaptive equalization to correct for communications characteristic of the cable, such as a loss associated with a transfer function of the cable, and/or to compensate for pre-emphasis applied to signals in the driver. The driver and/or receiver may operate in a voltage mode and/or in a current mode. In some embodiments, the cable may have a bandpass characteristic, i.e., a communication bandwidth characterized by a low-frequency threshold or cutoff (such as a low-frequency—3 dB point) and a high-frequency threshold or cutoff (such as a high-frequency −3 dB point).

In some embodiments, some or all of the functionality of the driver may be integrated into the serializer, for example, as an integrated circuit (IC), and/or some or all of the functionality of the receiver may be integrated into the de-serializer. In some embodiments, however, the driver and/or the receiver may be implemented using discrete components, including, for example, one or more circuits, an HDMI connector and a cable television connector (such as an F-style connector). In some embodiments, the serializer circuit may include a multiplexer that interleaves the data streams in the plurality of data streams into the serial data stream and may perform channel coding on the serial data stream such that a minimum frequency of content in the serial data stream exceeds the low-frequency threshold of the cable. In some embodiments, the de-serializer circuit may perform channel decoding on the serial data stream and may include a multiplexer that separates the data streams in the serial data stream into the plurality of data streams.

In some embodiments, the serializer circuit and the de-serializer circuit may further include an interface that allow communication of out-of-band or back channel information from the de-serializer circuit to the serializer circuit and/or from the serializer circuit to the de-serializer circuit. For example, the interface may be compatible with the back channel in HDMI, which has a maximum bandwidth of approximately 100 kb/s. The back channel information may be used to carry the data used in the back-channel of a standard interface such as HDMI, and may additionally be used to adjust the pre-emphasis, the channel coding, and/or the equalization of the signals corresponding to the serial data stream that are transmitted and received on the cable. In some embodiments, the back channel information may include control information, such as infrared remote control signals. The back channel information may have a maximum frequency that is less than the low-frequency threshold of the cable. Frequencies below the low-frequency threshold may constitute a low frequency band having reduced transmission capability. In some embodiments, the back channel information may have a maximum frequency that is less than the high-frequency threshold of the cable.

In exemplary embodiments, the cable may include a cable television cable, a twisted pair (such as CAT 5 cable), a twin coax cable, a cable having a characteristic impedance of substantially 50 Ω, and/or a cable having a characteristic impedance of substantially 75 Ω. Coax cables may be loosely grouped into two categories or classes. In a first class, often found in professional applications such as broadcast studios, the cable has a copper center conductor. Cables in the first class have transfer functions that extend down to DC, with no drop off, i.e., cables in the first class have a low-pass characteristic instead of a bandpass characteristic. In the second class, often found in residential or consumer applications, such as people's homes, the cable has a steel center conductor with a copper coating. While such cables, designed just to carry the higher frequencies of common broadcast and cable television, may have a lower cost, they also have transfer functions that have a bandpass characteristic. In addition, such cables may have a band of greater attenuation from DC to a lower cut-off frequency of the bandpass characteristic. As a consequence, cables in the second class may not communicate low-frequency content in the signals corresponding to the serial data stream very well, in particular, those frequencies that are less than the low-frequency threshold of the cable. This may limit a distance over which the signals corresponding to the serial data stream may be effectively communicated (i.e., without errors) on cables in the second class.

The embodiments of the driver and receiver may improve communication of the signals corresponding to the serial data stream on cables in the second class. As a consequence, the signals corresponding to the serial data stream may be communicated on such cables having a length greater than 5 m, 10 m, 20 m, 25 m, 30 m, 50 m, 75 m, 100 m or more. This improved functionality may allow the serial data stream corresponding to an interface standard, such as the digital video interface and/or HDMI, to be communicated using low-cost cables that are found in many residences. The embodiments described below, therefore, are compatible with legacy wiring found in many homes. Such embodiments offer lower cost and the ability to field terminate relative to optical links, which are described further below.

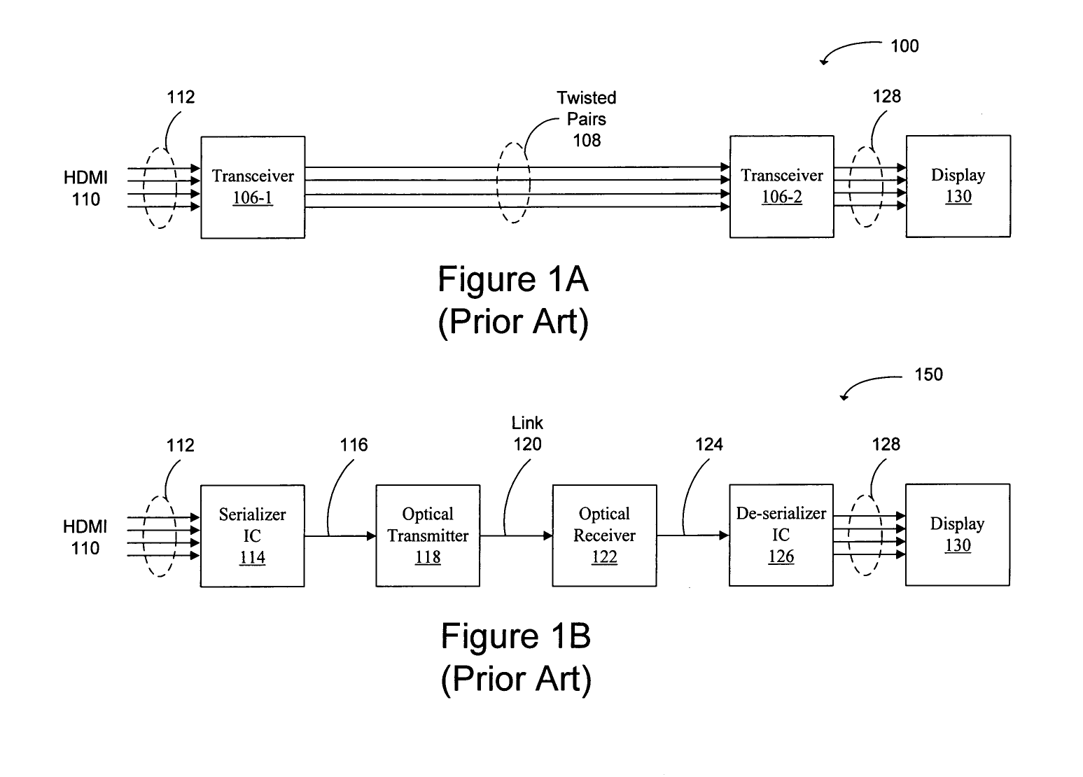

Existing approaches to communication of the signals often utilize twisted pairs of cables or an optical link, such as an optical fiber, between the serializer circuit and the de-serializer circuit. FIG. 1A illustrates an embodiment of an existing digital video interface system 100 where transceivers 106 communicate four data streams 112 corresponding to HDMI 110 using twisted pairs of cables 108. Received signals are output as four data streams 128, which correspond to HDMI 110. The four data streams 128 are coupled a display 130, such as a high-definition television. While not shown,. there may be additional uni-directional or bi-directional connections between the transceivers 106.

FIG. 1B illustrates another embodiment of an existing digital video interface system 150. The four data streams 112 corresponding to HDMI 110 are input to a serializer circuit 114. A serial data stream 116 is output to an optical transmitter 118. Optical signals are coupled via a link 120 (such as a fiber optic cable) to an optical receiver 122. A serial data stream 124 is output by the optical receiver 122 to a de-serializer circuit 126. The de-serializer circuit 126 outputs the four data streams 128 corresponding to HDMI 110 to the display 130. While the existing digital video interface system 150 allows communication of signals over extended distances, it utilizes optical components, such as the optical transmitter 118, the link 120 and the optical receiver 122, that may entail additional expense relative to the embodiments described below.

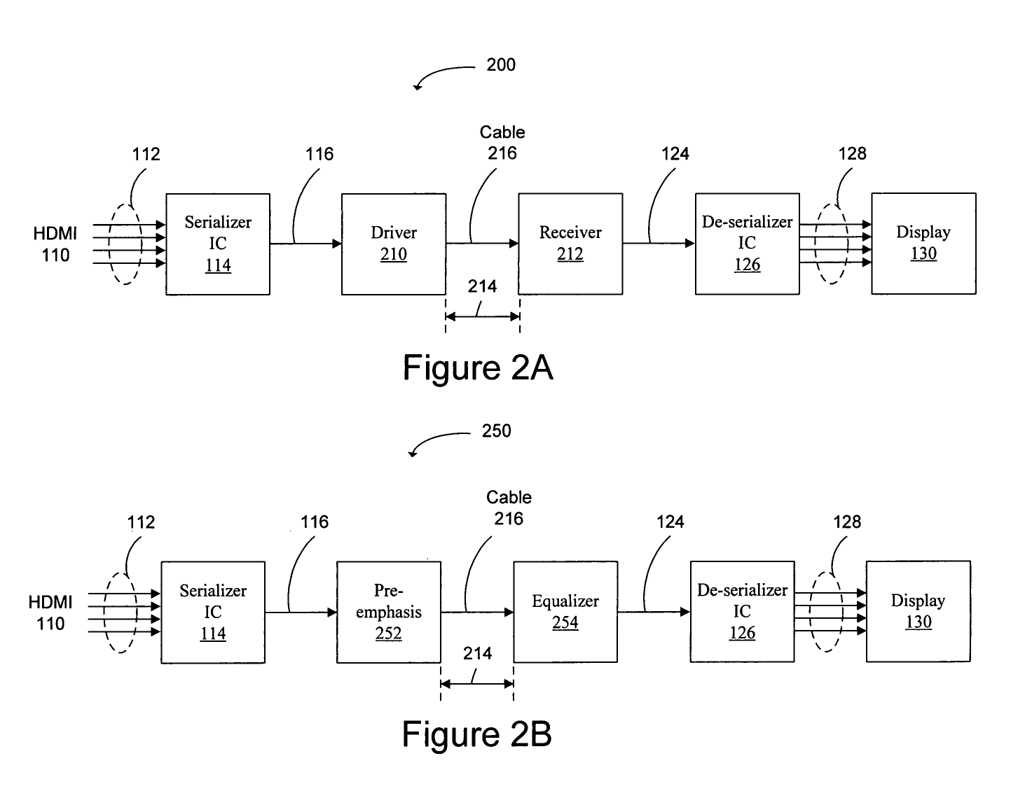

Attention is now directed towards embodiments of the digital video interface and related systems that may allow communication of the serial data stream, such as that corresponding to HDMI, using cables that convey electrical signals. FIG. 2A is a block diagram illustrating an embodiment of a digital video interface system 200. The four data streams 112 corresponding to HDMI 110 are input to the serializer circuit 114. The serial data stream 116 is output to a driver 210. Electrical signals are coupled via a cable 216 (such as a coaxial cable) to a receiver 212. The serial data stream 124 is output to the de-serializer circuit 126. The de-serializer circuit 126 outputs the four data streams 128 corresponding to HDMI to the display 130.

The driver 210 may include pre-emphasis and/or may perform a signal transformation corresponding to the impedance of the cable 216. The receiver 212 may include equalization and/or adaptive equalization to correct for pre-emphasis applied to signals in the driver and/or a communications characteristic of the cable 216. The driver 210 and/or the receiver 212 may allow communications of signals in the serial data stream 116 over a distance 214, such as 50 m.

In some embodiments, the digital video interface system 200 may include fewer or addition elements. Functions of two or more elements may be combined. A position of one or more elements may be changed.

FIG. 2B is a block diagram illustrating an embodiment of a digital video interface system 250. The driver 210 in the digital video interface system 200 has been replaced by a pre-emphasis element 252 and the receiver 212 in the digital video interface system 200 has been replaced by an equalizer 254. The equalizer 254 may be adaptive thereby allowing the digital video interface system 250 to accommodate a wide variety of cables, such as the cable 216, having a range of characteristics (such as transfer functions having different low-frequency thresholds and/or high-frequency thresholds) and/or different overall quality. Adaptive equalization in the equalizer 254 may be in accordance with information provided by the de-serializer circuit 126, the serializer circuit 114 and/or the pre-emphasis element 252. In some embodiments, the equalizer 254 may perform equalization in accordance with equalization instructions from a host. Equalization information may be provided using the out-of-band or back channel described previously. In some embodiments, the equalization information may be in-band and/or interleaved with data streams in the serial data stream 116. In some embodiments, the equalization information may be derived from pre-determined sequences.

In some embodiments, the digital video interface system 250 may include fewer or addition elements. Functions of two or more elements may be combined. A position of one or more elements may be changed.

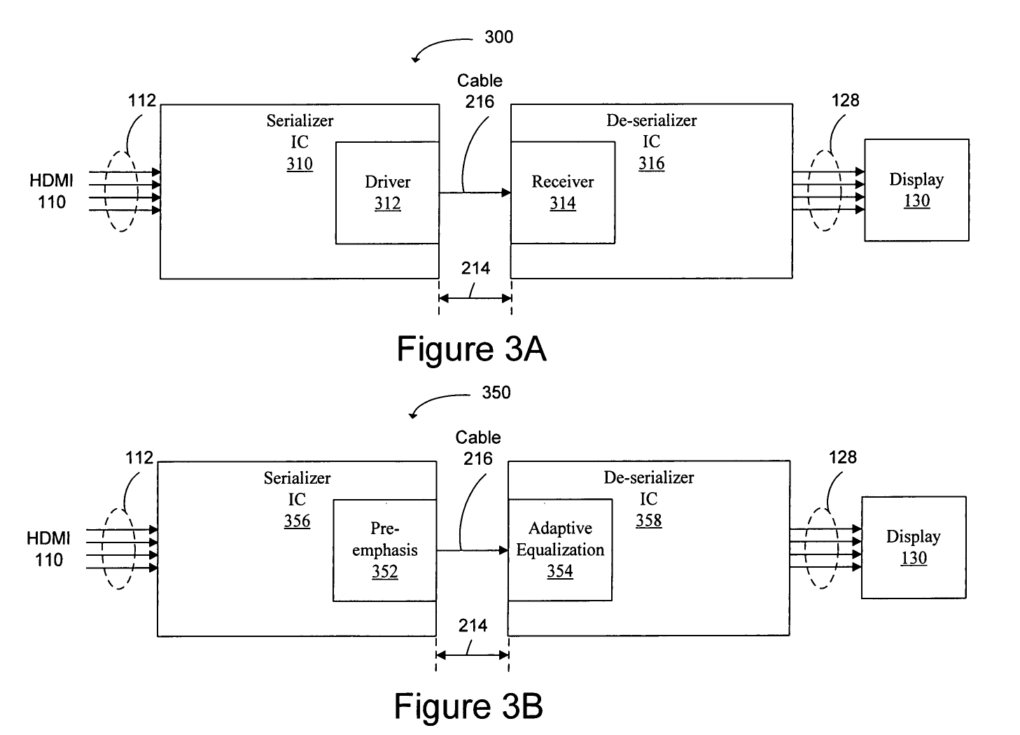

FIG. 3A is a block diagram illustrating an embodiment of a digital video interface system 300. The four data streams 112 corresponding to HDMI 110 are input to the serializer circuit 310. The serializer circuit 310 includes an integrated driver 312. The driver 312 may include pre-emphasis and/or may perform a signal transformation corresponding to the impedance of the cable. A serial data stream is output in the form of electrical signals on the cable 216. The signals are received by a de-serializer circuit 316. The de-serializer circuit 316 may include equalization and/or adaptive equalization to correct for a communications characteristic of the cable 216 or for excess or insufficient pre-emphasis applied to signals in the driver 312. The de-serializer circuit 316 outputs the four data streams 128 corresponding to HDMI to the display 130.

The serializer circuit 310 and the de-serializer circuit 316 may allow communication of signals in the serial data stream over the distance 214. In some embodiments, the digital video interface system 300 may include fewer or addition elements. Functions of two or more elements may be combined. A position of one or more elements may be changed.

FIG. 3B is a block diagram illustrating an embodiment of a digital video interface system 350. The driver 312 in the digital video interface system 300 has been replaced by a pre-emphasis element 352 and the receiver 314 in the digital video interface system 300 has been replaced by an equalizer 354. The equalizer 354 may be adaptive thereby allowing the digital video interface system 350 to accommodate a wide variety of cables, such as the cable 216, having a range of characteristics (such as transfer functions having different low-frequency thresholds and/or high-frequency thresholds) and/or different overall quality. Adaptive equalization in the equalizer 354 may be in accordance with information provided by a de-serializer circuit 358 and/or a serializer circuit 356. This information may be provided using the out-of-band channel described previously. In some embodiments, this information may be in-band and/or interleaved with data in the serial data stream on the cable 216.

The serializer circuit 356 and the de-serializer circuit 358 may allow communication of signals in the serial data stream over the distance 214. In some embodiments, the digital video interface system 350 may include fewer or addition elements. Functions of two or more elements may be combined. A position of one or more elements may be changed.

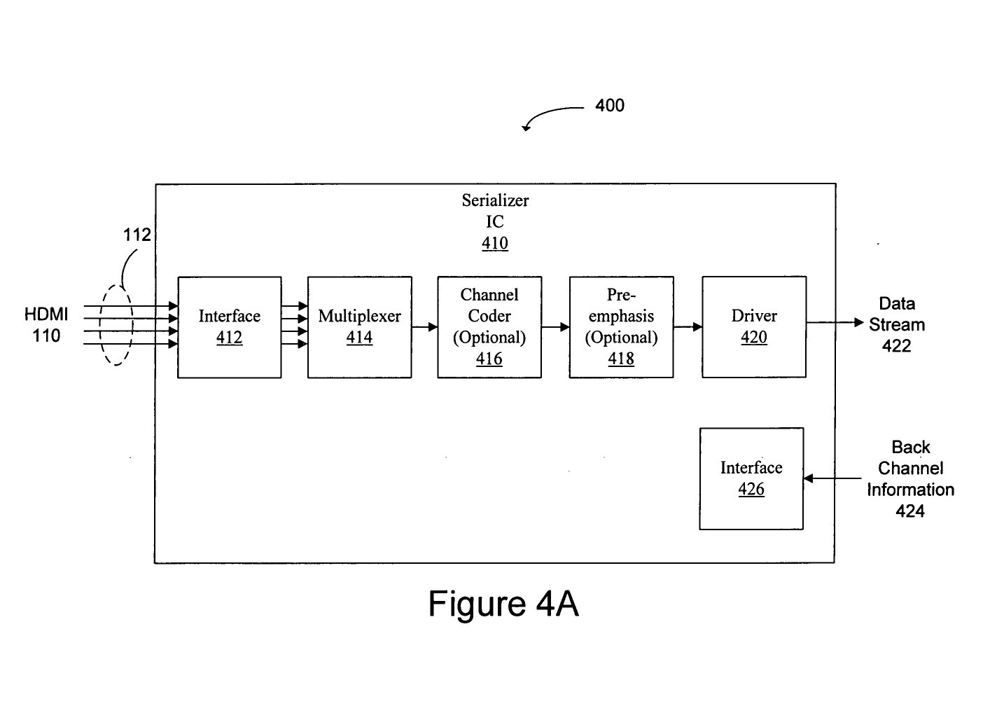

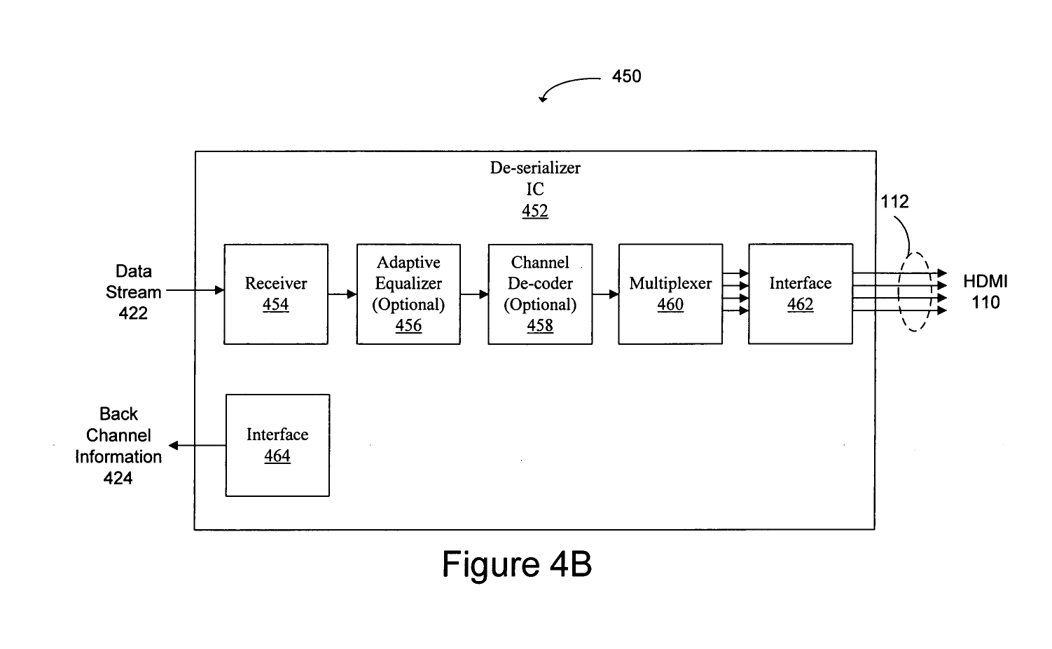

FIG. 4A is a block diagram illustrating an embodiment 400 of a serializer circuit 410. The serializer circuit 410 may includes an interface 412 for receiving the four signals 112 corresponding to HDMI 110, a multiplexer 414 that interleaves the data streams in the data streams in the four signals 112 into the serial data stream, optional channel coder 416 for coding the serial data stream such that the minimum frequency of content in the serial data stream exceeds the low-frequency threshold of the cable, optional pre-emphasis 418, and/or a driver 420 that may perform the signal transformation corresponding to the impedance of the cable to produce data stream 422. The serializer circuit 410 may also include an interface 426 to receive back channel information 424 from a de-serializer circuit, such as the de-serializer circuit 316 (FIG. 3A). In some embodiments, the interface 426 may be used to transmit back channel information 424 to a de-serializer circuit, such as the de-serializer circuit 316 (FIG. 3A). In some embodiments, the back channel information 424 and the four signals 112 may be communicated using the same or a common cable or link. In some embodiments, the serializer circuit 410 may include fewer or addition elements. Functions of two or more elements may be combined. A position of one or more elements may be changed.

FIG. 4B is a block diagram illustrating an embodiment 450 of a de-serializer integrated circuit 452. The de-serializer circuit 452 may includes a receiver 454 for receiving the data stream 422, an optional adaptive equalizer 456 to correct for or compensate for pre-emphasis applied to signals in the serializer circuit 410 (FIG. 4A) and/or a communications characteristic of the cable, such as a loss associated with the transfer fuiction of the cable, optional channel de-coder 458 to reverse the coding implemented by the optional channel coder 416 (FIG. 4A), a multiplexer 460 for separating the data streams in the serial data stream into the four signals 112 corresponding to HDMI 110, and/or an interface 462 for outputting the four signals 112 corresponding to HDMI 110. The optional adaptive equalizer 456 may be adjusted in accordance with information provided by the serializer circuit 410 (FIG. 4A) or the de-serializer circuit 452. The de-serializer circuit 452 may also include an interface 464 for transmitting back channel information 424 to a serializer circuit, such as the serializer circuit 410 (FIG. 4A). In some embodiments, the interface 464 may be used to receive back channel information 424 from a serializer circuit, such as the serializer circuit 410 (FIG. 4A). In some embodiments, the back channel information 424 and the four signals 112 may be communicated using the same or a common cable or link. In some embodiments, the de-serializer circuit 452 may include fewer or addition elements. Functions of two or more elements may be combined. A position of one or more elements may be changed.

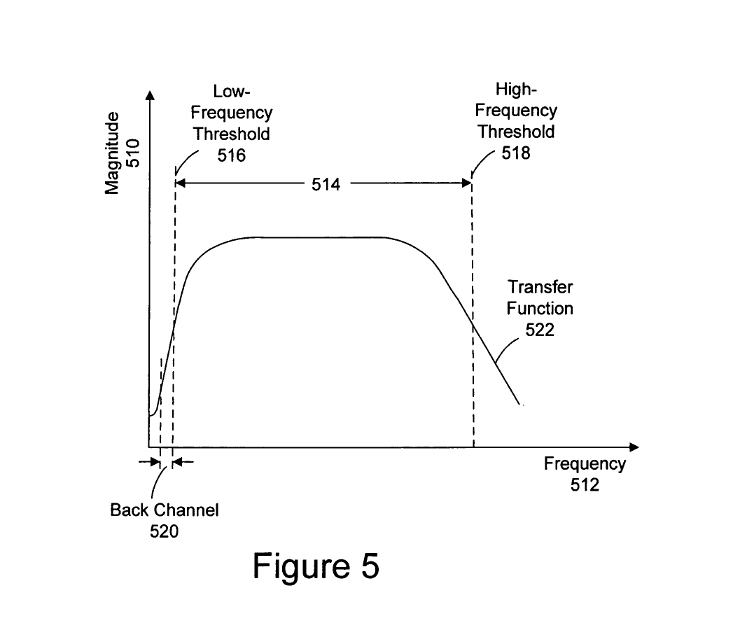

FIG. 5 is a block diagram illustrating an embodiment of a communications bandwidth 514 of a cable, such as the cable 216 (FIG. 2A). A magnitude 510 of a transfer function 522 is illustrated as a function of frequency 512. A low-frequency threshold 516 and a high-frequency threshold 518 correspond to the communications bandwith 514. A range of frequencies lower than the low-frequency threshold 516 may be used as a back channel 520. In some embodiments, at low frequencies, below the low-frequency threshold 516, the transfer function 522 may exhibit a plateau. A ratio of the magnitude of this plateau to a peak magnitude of the transfer function 522 may correspond to the ratio of the conductivity of steel to that of copper.

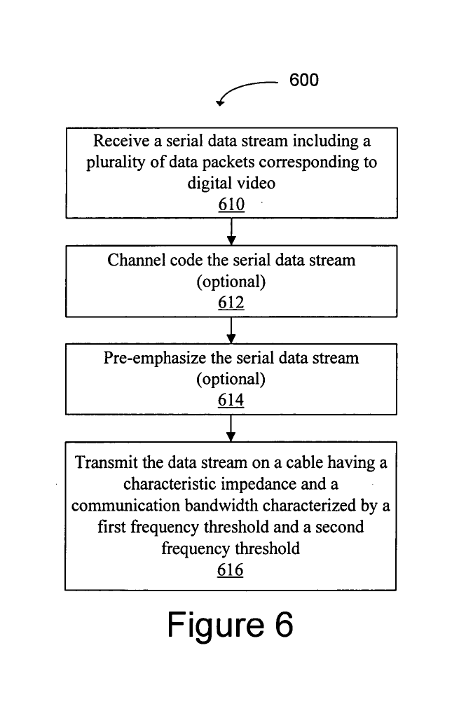

Attention is now directed towards embodiments of processes for operating a serializer circuit and/or a de-serializer circuit. FIG. 6 is a flow diagram illustrating a method of operation 600 of an embodiment of a digital video interface driver. A serial data stream including a plurality of data streams corresponding to digital video is received (610). The serial data stream is optionally channel coded (612). The serial data stream is optionally pre-emphasized (614). The data stream is transmitted on a cable having a characteristic impedance and a communication bandwidth characterized by a first frequency threshold and a second frequency threshold (616). In some embodiments, the first and second frequency thresholds may define a bandwidth. In some embodiments, the method of operation 600 may include fewer or additional operations, two or more operations may be combined into a single operation, and/or an order of two or more operations may be changed.

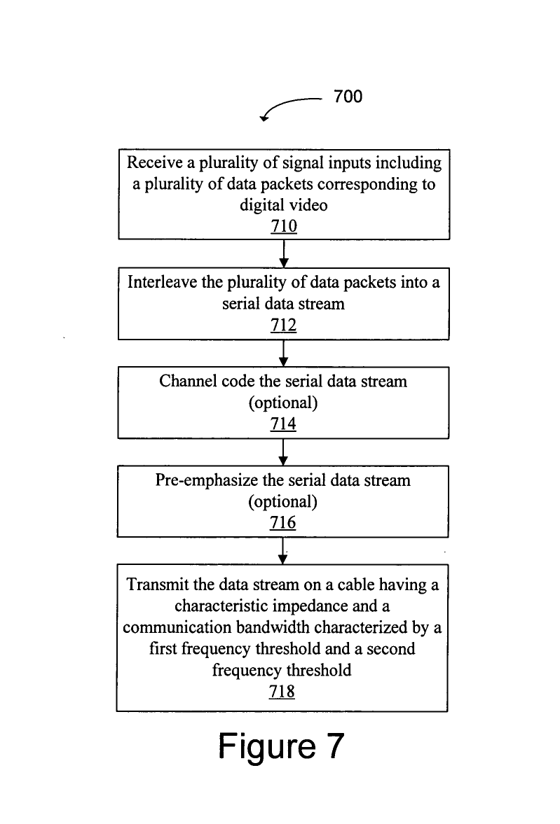

FIG. 7 is a flow diagram illustrating a method of operation 700 of an embodiment of a digital video interface circuit. A plurality of signal inputs including a plurality of data streams corresponding to digital video are received (710). The plurality of data streams are interleaved into a serial data stream (712). The serial data stream is optionally channel coded (714). The serial data stream is optionally pre-emphasized (716). The data stream is transmitted on a cable having a characteristic impedance and a communication bandwidth that may be characterized by a first frequency threshold and a second frequency threshold (718). In some embodiments, the method of operation 700 may include fewer or additional operations, two or more operations may be combined into a single operation, and/or an order of two or more operations may be changed.

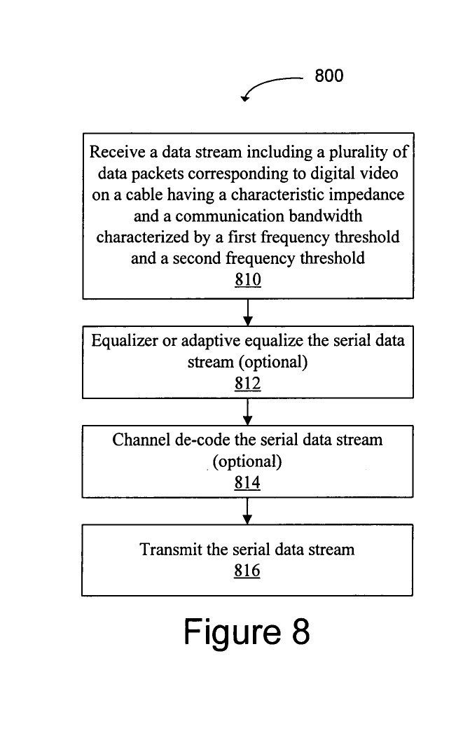

FIG. 8 is a flow diagram illustrating a method of operation 800 of an embodiment of a digital video interface input circuit. A data stream including a plurality of data streams corresponding to digital video is received on a cable having a characteristic impedance and a communication bandwidth that may be characterized by a first frequency threshold and a second frequency threshold (810). The serial data stream is optionally equalized or adaptively equalized (812). The serial data stream is optionally channel de-coded (814). The serial data stream is transmitted (816). In some embodiments, the method of operation 800 may include fewer or additional operations, two or more operations may be combined into a single operation, and/or an order of two or more operations may be changed.

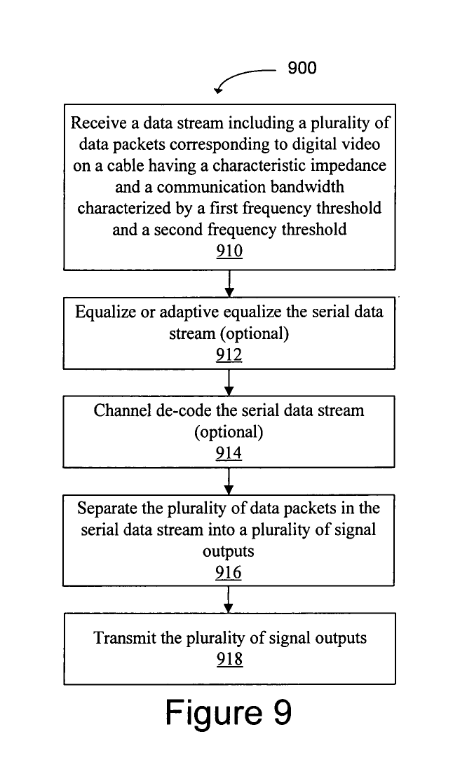

FIG. 9 is a flow diagram illustrating a method of operation 900 of an embodiment of a digital video interface circuit. A data stream including a plurality of data streams corresponding to digital video is received on a cable having a characteristic impedance and a communication bandwidth that may be characterized by a first frequency threshold and a second frequency threshold (910). The serial data stream is optionally equalized or adaptively equalized (912). The serial data stream is optionally channel de-coded (914). The plurality of data streams in the serial data steam are separated into a plurality of signal outputs (916). The plurality of signal outputs are transmitted (918). In some embodiments, the method of operation 900 may include fewer or additional operations, two or more operations may be combined into a single operation, and/or an order of two or more operations may be changed.

Devices and circuits described herein may be implemented using computer aided design tools available in the art, and embodied by computer readable files containing software descriptions of such circuits, at behavioral, register transfer, logic component, transistor and layout geometry level descriptions stored on storage media or communicated by carrier waves. Data formats in which such descriptions can be implemented include, but are not limited to, formats supporting behavioral languages like C, formats supporting register transfer level RTL languages like Verilog and VHDL, and formats supporting geometry description languages like GDSII, GDSIII, GDSIV, CIF, MEBES and other suitable formats and languages. Data transfers of such files on machine readable media including carrier waves can be done electronically over the diverse media on the Internet or through email, for example. Physical files can be implemented on machine readable media such as 4 mm magnetic tape, 8 mm magnetic tape, floppy disk media, hard disk media, CDs, DVDs, and so on.

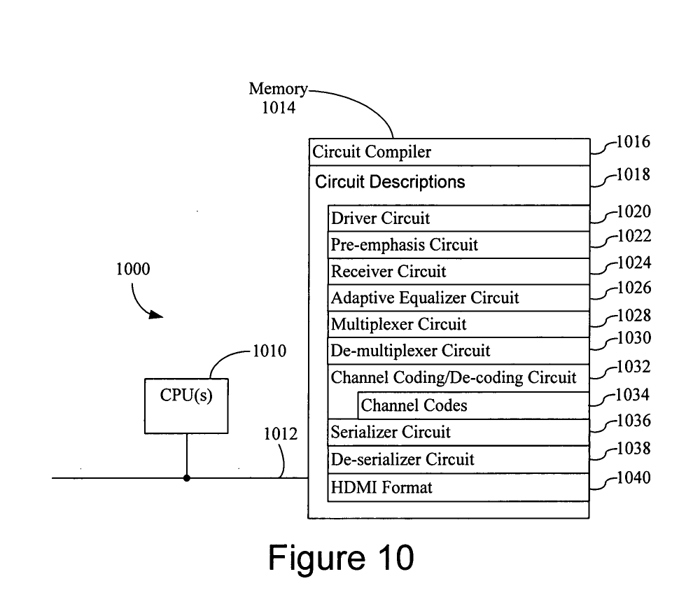

FIG. 10 is a block diagram illustrating an embodiment of a system 1000 for storing computer readable files containing software descriptions of the circuits. The system 1000 may include at least one data processor or central processing unit (CPU) 1010, a memory 1014 and one or more signal lines 1012 for coupling these components to one another. The one or more signal lines 1012 may constitute one or more communications buses.

The memory 1014 may include high-speed random access memory and/or non-volatile memory, such as one or more magnetic disk storage devices. The memory 1014 may store a circuit compiler 1016 and circuit descriptions 1018. The circuit descriptions 1018 may include a driver circuit 1020, a pre-emphasis circuit 1022, a receiver circuit 1024, an adaptive equalizer circuit 1026, a multiplexer circuit 1028, a de-multiplexer circuit 1030, a channel coding/de-coding circuit 1032, a serializer circuit 1036, a de-serializer circuit 1038 and an HDMI format 1040. The channel coding/de-coding circuit 1032 may include one or more channel codes 1034. The circuit descriptions 1018 may include descriptions of additional circuits, and in some embodiments may include only a subset of the circuit descriptions shown in the system 1000.

The foregoing descriptions of specific embodiments of the present invention are presented for purposes of illustration and description. They are not intended to be exhaustive or to limit the invention to the precise forms disclosed. Rather, it should be appreciated that many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A circuit, comprising:
a first interface to receive a plurality of data streams from a plurality of signal inputs, wherein the plurality of data streams correspond to digital video, and wherein the plurality of data streams are encoded using transition-minimized differential signaling;
a multiplexer to interleave the plurality of data streams into a serial data stream; and
an output driver, including pre-emphasis circuitry, to transmit the serial data stream on an output, wherein the output is configured to couple to a cable to convey electrical signals.

2. The circuit of claim 1, wherein the plurality of data streams correspond to a digital video interface format.

3. The circuit of claim 1, wherein the plurality of data streams correspond to a high definition multimedia interface format.

4. The circuit of claim 1, wherein the cable is selected from the group consisting of cable television cable, a twisted pair, a twin coax cable, a cable having a characteristic impedance of substantially 50 Ω, and a cable having a characteristic impedance of substantially 75 Ω.

5. The circuit of claim 1, wherein the output driver includes circuitry to perform a signal transformation corresponding to a first characteristic impedance of the cable.

6. The circuit of claim 1, wherein the cable has a length greater than a pre-determined value.

7. The circuit of claim 6, wherein the pre-determined value is 5 meters.

8. The circuit of claim 1, wherein the serial data stream has a data rate greater than 3 Gb/s.

9. The circuit of claim 1, wherein the cable has a communication bandwidth characterized by a first frequency threshold and a second frequency threshold, the first frequency threshold is less than the second frequency threshold, and wherein the circuit is configured to perform channel coding on the serial data stream such that a minimum frequency of content in the serial data stream exceeds the first frequency threshold.

10. The circuit of claim 1, further comprising a second interface to receive a return signal from a cable input, wherein the cable has a communication bandwidth characterized by a first frequency threshold and a second frequency threshold, the first frequency threshold is less than the second frequency threshold; and wherein the cable input is configured to couple to the cable, and the return signal has a maximum frequency that is less than the first frequency threshold.

11. An output driver circuit, comprising an output driver to receive a serial data stream including a plurality of data streams, to perform pre-emphasis and to transmit the serial data stream on an output,
wherein the plurality of data streams corresponds to digital video, the plurality of data streams are encoded using transition-minimized differential signaling, the output is configured to couple to a cable to convey electrical signals.

12. A circuit, comprising:
an interface to receive a serial data stream including a plurality of data streams from a signal input,
wherein the plurality of data streams correspond to digital video, the plurality of data streams are encoded using transition-minimized differential signaling, the signal input is configured to couple to a cable to convey electrical signals;
an adaptive equalizer to correct for pre-emphasis applied to the plurality of data streams and a communications characteristic of the cable; and
a de-multiplexer to separate the plurality of data streams into the serial data stream into a plurality signal outputs.

13. An input circuit, comprising an interface configured to receive a serial data stream including a plurality of data streams, to perform adaptive equalization and to transmit the serial data stream on an output,
wherein the plurality of data streams corresponds to digital video, the plurality of data streams are encoded using transition-minimized differential signaling, the input is configured to couple to a cable to convey electrical signals.

14. A circuit, comprising:
a first interface to receive a plurality of data streams from a plurality of signal inputs, wherein the plurality of data streams correspond to digital video having 1280 or more vertical lines and an aspect ratio of 16:9, and wherein the data streams are compatible with a digital video interface format;
a multiplexer to interleave the plurality of data streams into a serial data stream, wherein the serial data stream has a data rate greater than a pre-determined threshold; and
an output driver, including pre-emphasis circuitry, configured to transmit the serial data stream on an output, wherein the output is configured to couple to a cable to convey electrical signals.

15. A circuit, comprising:
a first means for receiving a plurality of data streams from a plurality of signal inputs, wherein the plurality of data streams correspond to digital video, and wherein the plurality of data streams are encoded using transition-minimized differential signaling;
a second means for interleaving the plurality of data streams into a serial data stream; and
a third means, including a pre-emphasis mechanism, for transmitting the serial data stream on an output, wherein the output is configured to couple to a cable to convey electrical signals.

16. A method, comprising:
receiving a serial data stream including a plurality of streams corresponding to digital video, wherein the plurality of data streams are encoded using transition-minimized differential signaling; and
pre-emphasizing and transmitting the serial data stream on an output, wherein the output is configured to couple to a cable to convey electrical signals.

17. A method, comprising:
receiving a serial data stream including a plurality of streams corresponding to digital video on an input, wherein the plurality of data streams are encoded using transition-minimized differential signaling, the input is configured to couple to a cable to convey electrical signals;
equalizing the serial data stream to correct for pre-emphasis applied to the plurality of data streams and a communications characteristic of the cable; and
transmitting the serial data stream.

18. A method, comprising:
receiving a plurality of signal inputs including a plurality of streams corresponding to digital video, wherein the plurality of data streams are encoded using transition-minimized differential signaling;
interleaving the plurality of data streams into a serial data stream; and
transmitting the serial data stream on an output, wherein the output is configured to couple to a cable to convey electrical signals.

19. A method, comprising:
receiving a serial data stream including a plurality of streams corresponding to digital video on an input, wherein the plurality of data streams are encoded using transition-minimized differential signaling, the input is configured to couple to a cable to convey electrical signals;
equalizing the serial data stream to correct for pre-emphasis applied to the plurality of data streams and a communications characteristic of the cable;
separating the plurality of data streams in the serial data stream into a plurality of signal outputs; and
transmitting the plurality of signal outputs.
